(19) United States
(12) Patent Application Publication
(10) Pub. No.: US 2025/0324523 A1
(43) Pub. Date: Oct. 16, 2025

(54) HOUSING FOR AN ELECTRONIC ELEMENT

(71) Applicant: Harman Professional Denmark ApS, Aarhus N (DK)

(72) Inventor: Niels Joergen Rasmussen, Egaa (DK)

(73) Assignee: Harman Professional Denmark ApS, Aarhus N (DK)

(21) Appl. No.: 19/249,338

(22) Filed: Jun. 25, 2025

Related U.S. Application Data
(63) Continuation of application No. PCT/EP2023/053594, filed on Feb. 14, 2023.

(30) Foreign Application Priority Data
Feb. 9, 2023 (DK) 202370074

(51) Int. Cl. H05K 5/02

(52) U.S. Cl. CPC H05K 5/0214; H05K 5/0212

(57) ABSTRACT

A housing having an opening and an outer surface circumferential around the opening. A first collar and a second collar project outwardly from the outer surface and extend circumferentially around the opening. A shielding element projects outwardly and extends circumferentially around a geometrical center of the cove. The first rim is closer to the geometrical center than the second rim. A carrying structure defines a passage from the exterior space to the inner space between the inner surface of the cover and the outer surface of the housing. At least one of the first and second collars overlaps at least one of the first and second rims in a plane perpendicular to the outer surface, and at least one of the first and second rims extends into the first space.

### CROSS-REFERENCE TO RELATED APPLICATION

This application is a continuation of International Application No. PCT/EP23/053594, filed on Feb. 14, 2023, which claims priority to application Ser. No. 20/237,0074, filed Feb. 9, 2023, in Denmark, each of which is incorporated by reference herein in its entirety.

### FIELD OF THE DISCLOSURE

The present disclosure relates to a housing for an electronic element, such as a lighting product, a loudspeaker, an amplifier, a sound mixer, or another electronic element, in particular to a ventilated housing with water ingress protection.

### BACKGROUND OF THE DISCLOSURE

In entertainment and architectural lighting and music industry, light fixtures, loudspeakers, and other electronic elements are often used outdoor with the risk of rain showers. Therefore, the product should either be placed safely under a roof, or it should be ingress protected.

### SUMMARY

It is an object of embodiments of the disclosure to provide an improved housing for an electronic element.

It is a further object of embodiments of the disclosure to provide a ventilated housing with water ingress protection.

The disclosure provides a housing for an electronic element, the housing comprising:
an opening between an exterior space outside the housing and an inner space inside the housing,
an outer surface circumferential around the opening,
a first collar and a second collar projecting outwardly from the outer surface and extending circumferentially around the opening, the first collar being closer to the opening than the second collar, and the first and second collars being separated by a first space,
a shielding element comprising a cover and first and second rims projecting outwardly from an inner surface of the cover and extending circumferentially around a geometrical center of the cover, the first rim being closer to the geometrical center than the second rim, and the first and second rims being separated by a second space, and
a carrying structure between the inner surface of the cover and the outer surface of the housing and carrying the shielding element at a distance from the outer surface of the housing to thereby define a passage from the exterior space to the inner space between the inner surface of the cover and the outer surface of the housing,
wherein at least one of the first and second collars overlaps at least one of the first and second rims in a plane perpendicular to the outer surface, and wherein at least one of the first and second rims extends into the first space.

By providing first and second collars projecting outwardly from the outer surface of the housing and first and second rims projecting outwardly from the inner surface of the cover, while the shielding element is carried at a distance from the outer surface, the opening can be protected from water, such as rain, while at the same time providing a passage between the inner space and the exterior space passing the first and second collars and the first and second rims to allow ventilation of the inner space. By ventilating the inner space, the risk of condensation in the inner space may be considerably reduced or even avoided.

To increase protection against water ingress, at least one of the first and second collars overlap at least one of the first and second rims in a plane perpendicular to the outer surface. This may provide a passage with hinderance for water, such as a flow of water or water droplets.

At least one of the first and second rims extends into the first space provided between the first and second collars. When at least one of the first and second rims extends into the first space between the first and second collars, the passage may form a zig-zag path between the inner surface of the cover and the outer surface of the housing.

Additionally, at least one of the first and second collars may extend into the second space provided between the first and second rims. In an alternative embodiment, none of the first and second collars extends into the second space. This may still provide an obstructed passage to reduce the risk of water ingress.

The housing may further comprise a third collar projecting outwardly from the outer surface and extending circumferentially around the opening, where the first and second collars may be closer to the opening than the third collar. A third collar arranged circumferentially around the opening and around the first and second collars, may provide additional obstruction to the passage from the exterior space to the inner space.

The first collar and the second collar may each terminate in respective free collar ends, where the first and second collars may each have a height being defined as a distance from the outer surface to the respective free collar ends. In one embodiment, the first and second collars may be of the same height. In an alternative embodiment, the first collar may have a height being smaller or larger than the height of the second collar.

The first rim and the second rim may each terminate in respective free rim ends, where the first and second rims may each have a height being defined as a distance from the inner surface of the cover to the respective free rim ends. In one embodiment, the second rim may have a height being larger than the first rim. This may ensure a larger overlap between the second rim and the second collar to provide a larger obstruction closer to the exterior space. In an alternative embodiment, the first and second rims may be of the same height.

The third collar may extend towards the second rim, where the third collar and the second rim may be aligned along a longitudinal direction of the third collar and the second rim. The third collar and the second rim may define a common surface which may define an outer boundary of the shielding element. A free end of third collar and a free end of the second rim may be arranged at a distance to each other to provide an entrance for the passage.

The second collar may comprise at least one drainage opening to provide drainage from the first space to the exterior space via the at least one drainage opening. If water ingress should not be fully avoided, water may be drained from the first space via the at least one drainage opening. In embodiment, where the second collar forms a non-circular shape in a cross-section parallel to the outer surface, the at least one drainage opening may be arranged at a corner of the second collar, such as at each corner. Thus, in one or more embodiments where the second collar is substantially square shaped in a cross-section parallel to the outer surface, a drainage opening may be arranged at one or more of the corners.

At least one wall portion may extend outwardly from the second collar along the at least one drainage opening to provide flow guidance towards the exterior space. By providing a flow guidance, flow toward the exterior space may be facilitated, while at the same time at least partly hindering a water flow in the opposite direction.

In one embodiment, the cover may comprise at least one aperture to provide passage through the cover. The aperture may have the shape of a circular hole, a triangular hole, a substantially C-shaped hole, a U-shaped hole, or another shape in a cross-section parallel to the inner surface of the cover.

The housing may further comprise a base plate forming a second opening. The base plate may be attached to the outer surface so that the second opening is aligned with the opening to secure that the opening is not blocked by the base plate. The first and second collars may form part of the base plate which may be arranged so that he first and second collars project outwardly from to outer surface of the housing.

By providing the first and second collars on a base plate, the base plate may together with the shielding element form a separate structure which together with the carrying structure may be easily replaceable. Furthermore, it may be used to protect the inner space of existing housings with an opening.

The housing may further comprise a filter element which may be located in a first enclosure encircled by the first collar. The filter element may extend transverse to the opening to protect the inner space of the housing. The filter element may be configured for removal of e.g. dust, pollen, and other unwanted materials.

The housing may further comprise an absorption element attached to the inner surface of the cover. The absorption element may be located in a second enclosure encircled by the first rim. The absorption element 162 may be arranged to absorb droplets and/or moisture to reduce the risk of moisture ingress into the inner space. In one embodiment, the absorption element May be a sheet of felt, such as a felt made of natural fibres and/or synthetic fibres.

The housing may further comprise a fan unit located in the inner space, where the fan unit may be configured to provide an air flow between the exterior space and the inner space. The air flow provided may assist ventilation of the inner space to reduce the risk of damaging the electronic element due to condensation. The air flow may further be used to compensate for a pressure loss over a filter element which may be arranged transverse to the opening. Furthermore, the air flow may be used to remove heat generated by the electronic element(s) in the housing.

### BRIEF DESCRIPTION OF THE DRAWINGS

Embodiments of the disclosure will now be further described with reference to the drawings, in which:

FIG. 1 illustrates an exploded view of a housing for an electronic element;

FIG. 2 illustrates a cross-sectional view of a housing;

FIG. 3 illustrates parts of a housing;

FIG. 4 illustrates a housing;

FIG. 5 illustrates parts of a housing;

FIG. 6 illustrates parts of a housing from above; and

FIG. 7 illustrates a cover for at housing from below.

### DESCRIPTION OF EMBODIMENTS

It should be understood that the detailed description and specific examples, while indicating embodiments of the disclosure, are given by way of illustration only, since various changes and modifications within the scope of the disclosure will become apparent to those skilled in the art from this detailed description.

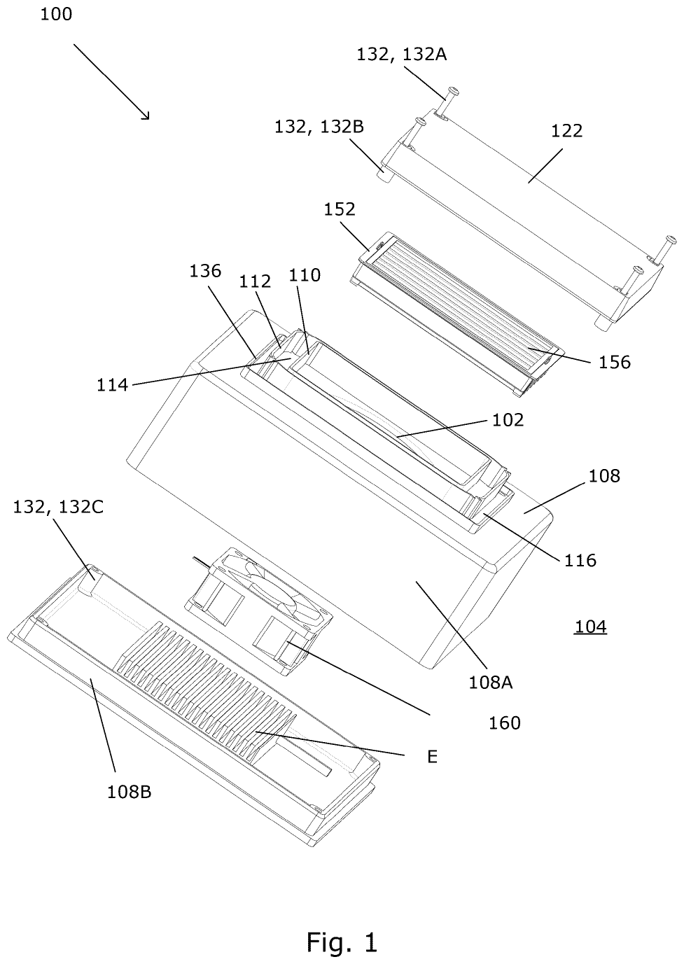

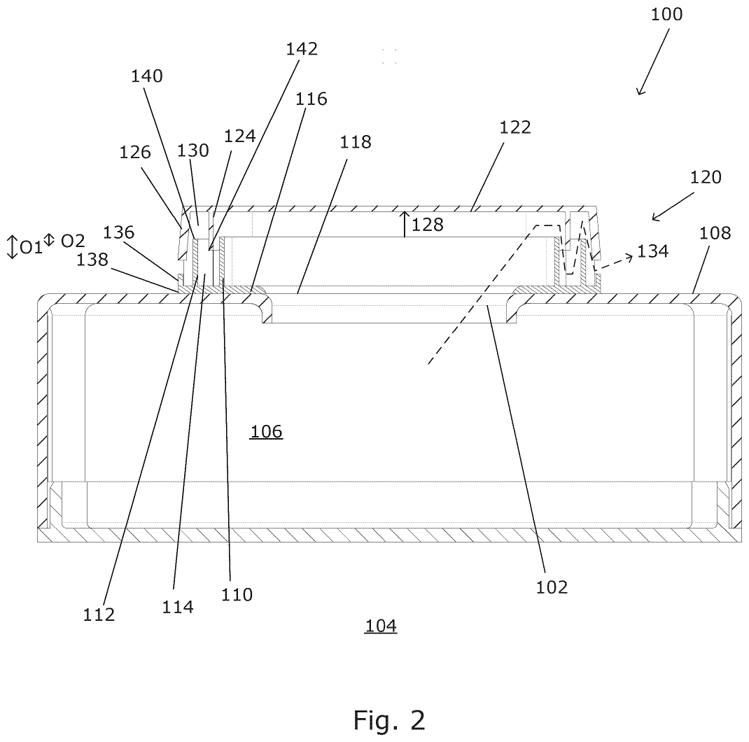

FIGS. 1 and 2 illustrate a housing 100 for an electronic element E. In FIG. 1, the housing 100 is illustrated in an exploded view, whereas FIG. 2 illustrates a cross-section through the housing 100.

The electronic element E could as an example be a lighting product, a loudspeaker, an amplifier, a sound mixer, or another electronic element. In the illustrated embodiment, the electronic element E is in the form of a power supply.

The housing 100 comprises an opening 102 between an exterior space 104 outside the housing 100 and an inner space 106 inside the housing 100. The housing 100 may be box-shaped as illustrated in FIG. 1. However, in an alternative embodiment, the housing 100 may be tubular, or may in a cross-section be triangular, oval, or of any other shape.

The housing 100 comprises an outer surface 108 circumferential around the opening 102. In the illustrated embodiment, the opening 102 is provided in an outer surface 108 forming one of four walls of the housing. The housing 100 may be formed by an upper part 108A and a lower part 108B, where the outer surface 108 may be an outer surface of either the upper or lower part 108A, 108B. The lower part 108B forms a tray-shaped element in which the power supply E is arranged.

The opening 102 could be circular, rectangular, oval, triangular, or of any other shape. In the illustrated embodiment, the opening 102 is circular.

A first collar 110 and a second collar 112 project outwardly from the outer surface 108. In the illustrated embodiment, the first and second collars 110, 112 extend substantially perpendicular from the outer surface 108. In an alternative embodiment, the first and second collars 110, 112 may extend at an angle to perpendicular from the outer surface 108, such as an angle of up to +/−25 degrees from perpendicular.

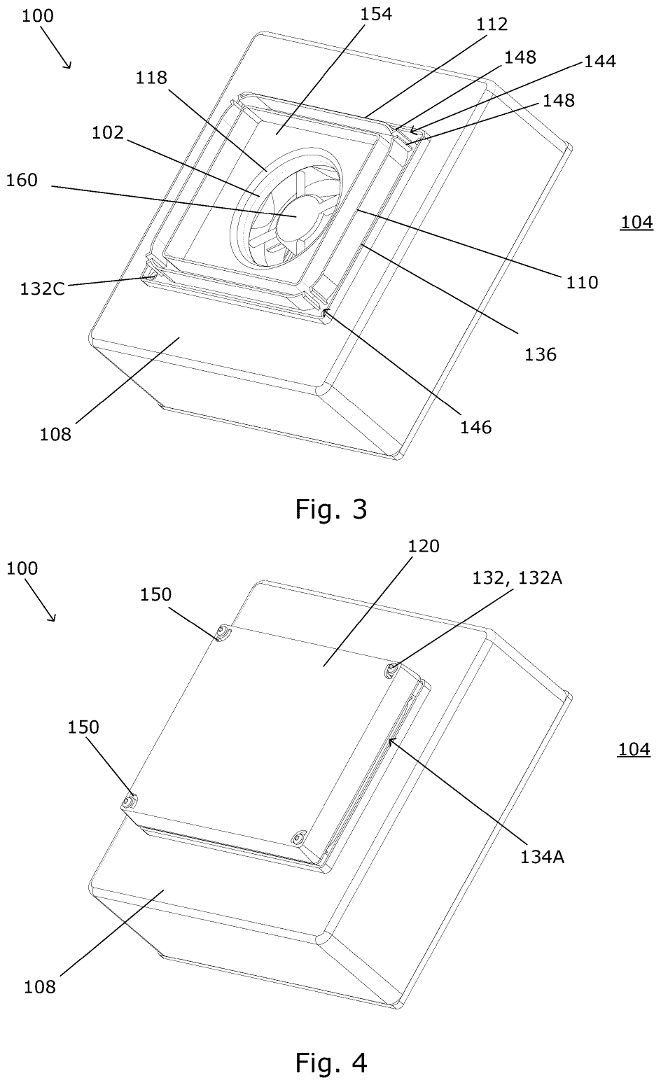

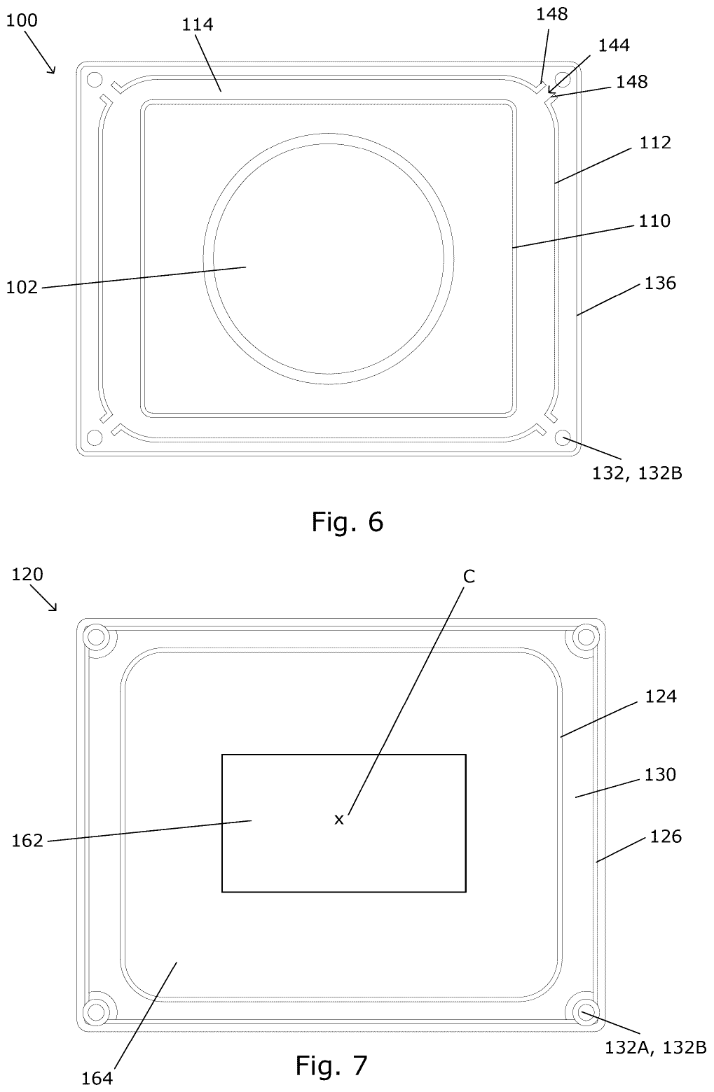

The first and second collars 110, 112 extend circumferentially around the opening 102 (see FIGS. 3 and 6), where the first collar 110 is closer to the opening 102 than the second collar 112. The first and second collars 112, 112 are separated by a first space 114.

In the illustrated embodiment, the first and second collars 110, 112 are substantially rectangular in a cross-section along the outer surface 108. Thus, the first and second collars 110, 112 are of another shape than the opening 102 having a circular shape. In an alternative embodiment, the cross-sectional shape of the first and second collars 110, 112 may be of the same shape as the opening 102. In a further alternative, the cross-sectional shape of the first collar 110 may be different than the cross-sectional shape of the second collar 112.

The housing 100 could further comprise a base plate 116 forming a second opening 118. The base plate 116 could be attached to the outer surface 108 so that the second opening 118 is aligned with the opening 102. The first and second collars 110, 112 could form part of the base plate 116. The base plate 116 and the first and second collar 110, 112 may be formed in one piece, e.g., by moulding. Alternatively, the first and second collars 110, 112 may be formed as separate elements which may subsequently be attached to the base plate 116. Thus, the first collar 110 and the second collar 112 may project outwardly from the outer surface 108, while forming part of a base plate 116 being attached to the outer surface 108.

The housing 100 further comprises a shielding element 120 which may be arranged to at least partly shield the opening 102 from rain falling onto the housing. The shielding element 120 comprises a cover 122 and first and second rims 124, 126 (see FIG. 2) projecting outwardly from an inner surface 128 of the cover 122. The shielding element 120 may be arranged with the inner surface 128 facing the opening 102.

The first and second rims 124, 126 extend circumferentially around a geometrical center C of the cover 122 (see FIG. 7), where the first rim 124 is closer to the geometrical center C than the second rim 126. The first and second rims 124, 126 are separated by a second space 130.

A carrying structure 132A, 132B, 132C is arranged between the inner surface 128 of the cover 122 and the outer surface 108 of the housing 100. The carrying structure 132A, 132B, 132C is carrying the shielding element 120 at a distance from the outer surface 108 of the housing 100 to thereby define a passage 134 (see FIG. 2) from the exterior space 104 to the inner space 106 between the inner surface 128 of the cover 122 and the outer surface 108 of the housing 100. In FIG. 2., the passage 134 is indicated by a dotted line. When the carrying structure 132 is arranged between the inner surface 128 of the cover 12 and the outer surface 108 of the housing 100, the first and second rims 124, 126 extend towards the outer surface 108.

By providing first and second collars 110, 112 projecting outwardly from the outer surface 108 of the housing 100 and first and second rims 124, 126 projecting outwardly from the inner surface 128 of the cover 122, while the shielding element 120 is carried at a distance from the outer surface 108, the opening 102 can be protected from rain, while at the same time providing a passage 134 between the inner space 106 and the exterior space 104 passing the first and second collars 110, 112 and the first and second rims 124, 126 to allow ventilation of the inner space 106. Ventilation of the inner space 106 may reduce or even avoid the risk of condensation in the inner space 106.

In the illustrated embodiment, the carrying structure 132 comprises four bolts 132A, each with an outer threading engaging an inner threading of a tubular carrier 132B (see FIG. 7). Four tubular carries 132B are arranged between the base plate 116 and the inner surface 128 of the cover 122. In an alternative embodiment, the tubular carriers 132B may be arranged on the outer surface 108.

In a further alternative, the carrying structure 132 may comprise matching structures 132A, 132B, where one 132B may attached to the outer surface 108 and the corresponding one 132A may form part of or being attached to the shielding element 120. The carrying structure 132 may as an example comprise snap-fit structures, geometrical locking structures attached to each other by frictional forces, or other locking structures.

By providing the carrying structure 132 carrying the shielding element 120 at a distance from the outer surface 108 of the housing 100 to thereby define a passage 134 from the exterior space 104 to the inner space 106 between the inner surface 128 of the cover 122 and the outer surface 108 of the housing 100, the inner space 106 may be ventilated by an air via the passage 134, which air flow may have a reduced pressure loss, as the first and second collars 110, 112 extend circumferentially around the opening 102, and as the first and second rims 124, 126 extend circumferentially around the geometrical center C of the cover thereby providing a larger area of the passage 134, while at the same time providing hinderance for rain falling on the housing 100.

As illustrated in FIG. 2, the first and second collars 110, 112 may overlap the first and second rims 124, 126 in a plane perpendicular to the outer surface 108. The overlaps O1, O2 are indicated with arrows in FIG. 2. In the illustrated embodiment, the first overlap O1 between the second collar 112 and the second rim 126 is larger than the second overlap O2 between the first and collars 110, 112 and the first rim 124. By providing one or more overlaps O1, O2 between at least some of the first and second collars 110, 112 and the first and second rims 124, 126, the passage 134 may be better protected against rain falling on the housing 100.

The first and second collars 110, 112 are separated by a first space 114. In the illustrated embodiment, the first rim 124 extends into the first space 114, which may provide an obstruction of the passage 134 to further protect the passage 134 against water flow while at the same time allowing an air flow through the passage 134 to ventilate the inner space 106.

The first and second rims 124, 126 are separated by a second space 130. In the illustrated embodiment, the first collar 110 extends into the second space 130. This may further increase protection of the passage 134 against water flow.

The housing 100 could further comprise a third collar 136 projecting outwardly from the outer surface 108 and extending circumferentially around the opening 102 as illustrated in FIG. 1. The first and second collars 110, 112 could be closer to the opening 102 than the third collar 136 which may be arranged as the outermost collar. The third collar 136 may be arranged along an outer edge 138 of the base plate 116. The third collar 136 may increase protection against water ingress into the inner space 106 even further. One or more further collars may in different embodiments be arranged circumferentially around the opening 102 and around the first and second collars 110, 112.

The third collar 136 may extend towards the second rim 126, and the third collar 136 and the second rim 126 may be aligned along the longitudinal direction of the third collar and the second rim, where the longitudinal direction may be defined as the direction in which the third collar 136 and the second rim 126 have their largest dimension. The distance between the free collar end 140 and the free rim end 142 may be in the range of 1-5 mm, such as in the range of 2-3 mm.

The first, second, and third collars 110, 112, 136 may terminate in respective free collar ends 140. The first, second, and third collars 110, 112, 136 may each have a height being defined as the distance from the outer surface 108 of the housing 100 to their respective free collar ends 140. In the illustrated embodiment, the first and second collars 110, 112 are substantially of the same height, whereas the third collar 136 has a height being smaller. In an alternative embodiment, the height of each of the collars 110, 112, 136 may be identical, whereas the height of each of the collars 110, 112, 136 in one or more further alternative embodiments may all be different. The height of the first, second, and third collars 110, 112, 136 may be in the range of 2-20 mm, such a 2-10 mm, such as 2-8 mm.

The first and second rims 124, 126 may terminate in respective free rim ends 142. The first and second rims 124, 126 may each have a height being defined as the distance from the inner surface 128 of the cover 122 to their respective free rim ends 142. The second rim 126 may have a height being larger than the first rim 124. In an alternative embodiment, the first and second rims 124, 126 may be of substantially the same height. The height of the first and second rims 124, 126 may be in the range of 2-20 mm, such a 2-10 mm, such as 2-8 mm. The height of the collars 110, 112, 136 and the height of the rims 124, 126 may depend on the size of the housing 100 and/or the size of the opening 102 and/or the distance from the collars/rims to a center of the opening.

FIG. 3 illustrates parts of the housing 100 also illustrated in FIGS. 1 and 2. In FIG. 3, the shielding clement 120 (see FIGS. 1 and 2) has been removed. FIG. 4 illustrates the housing 100 with the shielding element 120 arranged in front of the opening 102 at a distance from the outer surface 108 to thereby define a passage 134 from the exterior space 104 to the inner space 106. Only the entrance 134A of the passage 134 is illustrated in FIG. 4. The entrance 134A may extend along the entire circumference of the shielding element 120.

FIG. 3 illustrates the first and second collars 110, 112 projecting outwardly from the outer surface 108 and extending circumferentially around the opening 102, where the first collar 110 is closer to the opening 102 than the second collar 110, and where the first and second collars 110, 112 are separated by a first space 114.

In the illustrated embodiment, the second collar 112 comprises four drainage openings 144 (see also FIG. 6) to provide drainage from the first space 114 to the exterior space 104 via the drainage openings 144. A drainage opening 144 is located at each corner 146 of the second collar 112. By the provision of one or more drainage openings, it may be possible to drain the first space 114, if water ingress to the first space 114 has not been fully prevented by the first and second collars 110, 112 and the first and second rims 124, 126. The drainage openings 144 may further provide the possibility of having a second collar 112 with a height being larger or of same height as the first collar 110.

To facilitate a flow in a direction from the first space 114 towards the exterior space 104, at least one wall portion 148 may extend outwardly from the second collar 112 along the at least one drainage opening 144 to provide flow guidance towards the exterior space 104. In the illustrated embodiment, a wall portion 148 extending outwardly from the second collar 112 is arranged along each drainage opening 144 along opposite sides of the drainage opening 144. This may increase the flow guidance towards the exterior space 104, while at the same time at least partly hindering water flow in the opposite direction.

Four opening 132C with an inner threading are in the illustrated embodiment, arranged in the base plate 116 for engagement with the bolt 132A to form part of the carrying structure 132.

The four openings 132C could be arranged outside the first space between the second collar 112 and the third collar 136.

As illustrated in FIG. 4, the cover 122 may comprise at least one aperture 150 to provide passage through the cover 122. In the illustrated embodiment, a C-shaped aperture 150 is provided in the area of each corner of the cover adjacent to the bolt 132A. The apertures 150 may be arranged to provide drainage from the inner surface 128 of the cover 122 to the exterior space 104. The apertures 150 may be provided with a flow guide structure like the wall portions 148 to facilitate a water flow towards the exterior space 104 and to partly hinder a flow in the opposite direction.

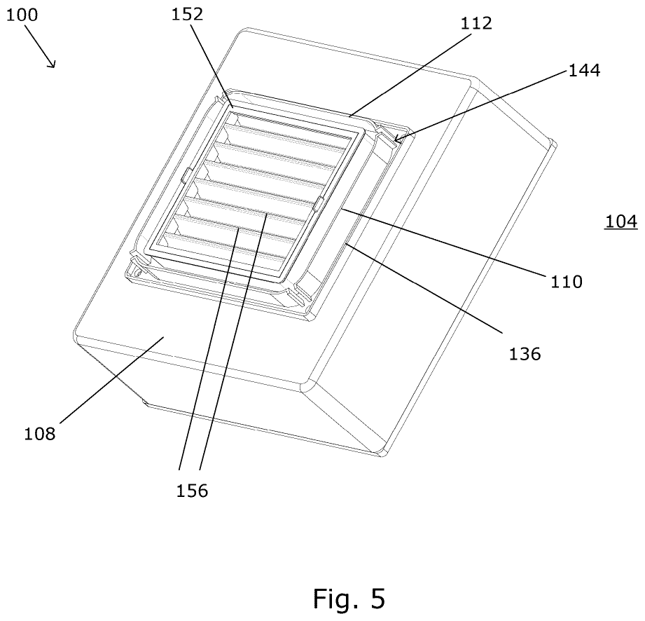

FIG. 5 illustrates parts of the housing 100 also illustrated in FIGS. 1 and 2. In FIG. 5, the shielding element 120 (see FIGS. 1 and 2) has been removed providing a similar view of the housing 100 as in FIG. 3. The housing 100 may further comprise a filter element 152 (see also FIG. 1) located in a first enclosure 154 (see FIG. 3) encircled by the first collar 110. The filter element 152 may be of a size fitting the size of the first enclosure 154. As the filter element 152 is inserted in the first enclosure 154, the first enclosure is not visible in FIG. 5.

The filter element 152 may have a height corresponding to the height of the first collar 110 to allow the filter element 152 to be fully inserted into the first enclosure 154. The filter element 152 may be configured for removal of dust and may extend transverse to the opening 102 to minimize the risk of dust, pollen, and other unwanted material being carried with an air flow to the inner space 106.

In the illustrated embodiment, the filter element 152 comprises a plurality of lamellas 156 forming a zig-zag pattern. In an alternative embodiment, the filter element 152 may be a foam element. Other types of filter elements 152 may also be used.

The housing 100 may further comprises a fan unit 160 located in the inner space 106 (see also FIGS. 1 and 3). The fan unit 160 may be configured to provide an air flow between the exterior space 104 and the inner space 106. The fan unit 160 may be configured to provide an air flow out of the inner space 106 to the exterior space 104 and/or to provide an air flow into the inner space 106 from the exterior space 104.

The air flow provided by the fan unit 160 may assist ventilation of the inner space 106 to reduce the risk of damaging the electronic element due to condensation. The air flow may further be used to compensate for the pressure loss over a filter element 152 which may be arranged transverse to the opening 102.

FIG. 6 illustrates a housing 100 from above without the cover 122 (see e.g., FIG. 1). The top view illustrates the first and second collars 110, 112 projecting outwardly from an outer surface 108 of the housing 100 and extending circumferentially around the opening 102. In the illustrated embodiment, the first and second collars 110, 112 are attached to a base plate 116. The housing 100 could comprise a third collar 136 projecting outwardly from the outer surface 108 and extending circumferentially around the opening 102, where the first and second collars 110, 112 are being arranged closer to the opening 102 than the third collar 136.

Four drainage openings 144 are arranged to provide drainage from the first space 114 to the exterior space 104 via the drainage openings 144. A wall portion 148 extending outwardly from the second collar 112 is arranged at each drainage opening 144 along opposite sides of the drainage opening 144. This may increase the flow guidance towards the exterior space 104, while at the same time at least partly hindering water flow in the opposite direction towards the first space 114.

FIG. 7 illustrates a cover 122 from below. The cover 122 forms part of a housing 100. The view from below illustrates the first and second rims 124, 126 projecting outwardly from an inner surface 128 of the cover 122 and extending circumferentially around the geometrical center C of the cover 122.

The housing 100 may further comprise an absorption element 162 attached to the inner surface 128 of the cover 122. The absorption element 162 may be located in a second enclosure 164 encircled by the first rim 124. The absorption element 162 may be of a size fitting the size of the second enclosure 164. Alternatively, the absorption element 162 may only take up a part of space of the second enclosure 164.

The absorption element 162 may be a sheet of felt, such as a felt made of natural fibres and/or synthetic fibres. The absorption element 162 may be arranged on the inner surface 128 to absorb droplets and/or moisture to reduce the risk of ingress into the inner space 106.

The following numbered embodiments are provided:

Embodiment 1. A housing for an electronic element, the housing comprising:
an opening between an exterior space outside the housing and an inner space inside the housing,
an outer surface circumferential around the opening,
a first collar and a second collar projecting outwardly from the outer surface and extending circumferentially around the opening, the first collar being closer to the opening than the second collar, and the first and second collars being separated by a first space,
a shielding element comprising a cover and first and second rims projecting outwardly from an inner surface of the cover and extending circumferentially around a geometrical center of the cover, the first rim being closer to the geometrical center than the second rim, and the first and second rims being separated by a second space, and
a carrying structure between the inner surface of the cover and the outer surface of the housing and carrying the shielding element at a distance from the outer surface of the housing to thereby define a passage from the exterior space to the inner space between the inner surface of the cover and the outer surface of the housing,
wherein at least one of the first and second collars overlaps at least one of the first and second rims in a plane perpendicular to the outer surface, and wherein at least one of the first and second rims extends into the first space.

Embodiment 2. The housing according to Embodiment 1, wherein at least one of the first and second collars extends into the second space.

Embodiment 3. The housing according to any of Embodiments 1-2, further comprising a third collar projecting outwardly from the outer surface and extending circumferentially around the opening, the first and second collars being closer to the opening than the third collar.

Embodiment 4. The housing according to any of the preceding Embodiments, wherein the first collar and the second collar terminate in respective free collar ends, the first and second collars each having a height being defined as a distance from the outer surface to the respective free collar ends, the first and second collars being of substantially the same height.

Embodiment 5. The housing according to any of the preceding Embodiments, wherein the first rim and the second rim terminate in respective free rim ends, the first and second rims each having a height being defined as a distance from the inner surface of the cover to the respective free rim ends, the second rim having a height being larger than the first rim.

Embodiment 6. The housing according to any of Embodiments 3-5, wherein the third collar extends towards the second rim, the third collar and the second rim being aligned along a longitudinal direction of the third collar and the second rim.

Embodiment 7. The housing according to any of the preceding Embodiments, wherein the second collar comprises at least one drainage opening to provide drainage from the first space to the exterior space via the at least one drainage opening.

Embodiment 8. The housing according to Embodiment 7, wherein at least one wall portion extends outwardly from the second collar along the at least one drainage opening to provide flow guidance towards the exterior space.

Embodiment 9. The housing according to any of the preceding Embodiment 8, wherein the cover comprises at least one aperture to provide passage through the cover.

Embodiment 10. The housing according to any of the preceding Embodiments, further comprising a base plate forming a second opening, the base plate being attached to the outer surface so that the second opening is aligned with the opening, wherein the first and second collars form part of the base plate.

Embodiment 11. The housing according to any of the preceding Embodiments, further comprising a filter element located in a first enclosure encircled by the first collar, the filter element extending transverse to the opening.

Embodiment 12. The housing according to any of the preceding Embodiments, further comprising an absorption element attached to the inner surface of the cover and located in a second enclosure encircled by the first rim.

Embodiment 13. The housing according to any of the preceding Embodiments, further comprising a fan unit located in the inner space, the fan unit being configured to provide an air flow between the exterior space and the inner space.

1. A housing for an electronic element, the housing comprising:
an opening between an exterior space outside the housing and an inner space inside the housing;
an outer surface circumferential around the opening;
a first collar and a second collar projecting outwardly from the outer surface and extending circumferentially around the opening, the first collar being closer to the opening than the second collar, and the first and second collars being separated by a first space;
a shielding element comprising a cover and first and second rims projecting outwardly from an inner surface of the cover and extending circumferentially around a geometrical center of the cover, the first rim being closer to the geometrical center than the second rim, and the first and second rims being separated by a second space; and
a carrying structure between the inner surface of the cover and the outer surface of the housing and carrying the shielding element at a distance from the outer surface of the housing to thereby define a passage from the exterior space to the inner space between the inner surface of the cover and the outer surface of the housing;
wherein at least one of the first and second collars overlaps at least one of the first and second rims in a plane perpendicular to the outer surface and wherein at least one of the first and second rims extends into the first space.

2. The housing according to claim 1, wherein at least one of the first and second collars extends into the second space.

3. The housing according to claim 1, wherein the first collar and the second collar terminate in respective free collar ends, the first and second collars each having a height being defined as a distance from the outer surface to the respective free collar ends, the first and second collars being of substantially the same height.

4. The housing according to claim 2, wherein the first rim and the second rim terminate in respective free rim ends, the first and second rims each having a height being defined as a distance from the inner surface of the cover to the respective free rim ends, the second rim having a height being larger than the first rim.

5. The housing according to claim 1, wherein the second collar comprises at least one drainage opening to provide drainage from the first space to the exterior space via the at least one drainage opening.

6. The housing according to claim 5, wherein at least one wall portion extends outwardly from the second collar along the at least one drainage opening to provide flow guidance towards the exterior space.

7. The housing according to claim 1, wherein the cover comprises at least one aperture to provide passage through the cover.

8. The housing according to claim 1, further comprising a base plate forming a second opening, the base plate being attached to the outer surface so that the second opening is aligned with the opening, wherein the first and second collars form part of the base plate.

9. The housing according to claim 1, further comprising a filter element located in a first enclosure encircled by the first collar, the filter element extending transverse to the opening.

10. The housing according to claim 1, further comprising a fan unit located in the inner space, the fan unit being configured to provide an air flow between the exterior space and the inner space.
